(19) United States
(12) Patent Application Publication
(10) Pub. No.: US 2020/0098819 A1
(43) Pub. Date: Mar. 26, 2020

(54) IMAGE SENSORS WITH HEATING EFFECT AND RELATED METHODS

(71) Applicant: SEMICONDUCTOR COMPONENTS INDUSTRIES, LLC, Phoenix, AZ (US)

(72) Inventors: Victor LENCHENKOV, Sunnyvale, CA (US); Hamid Reza SOLEIMANI, Cupertino, CA (US)

(73) Assignee: SEMICONDUCTOR COMPONENTS INDUSTRIES, LLC, Phoenix, AZ (US)

(21) Appl. No.: 16/695,383

(22) Filed: Nov. 26, 2019

Related U.S. Application Data
(63) Continuation-in-part of application No. 15/951,470, filed on Apr. 12, 2018.
Application No. 15/951,470 is a continuation of application No. 15/230,134, filed on Aug. 5, 2016, now Pat. No. 9,972,654.
Application No. 15/230,134 is a division of application No. 14/723,675, filed on May 28, 2015, now Pat. No. 9,431,443.

(51) Int. Cl. H01L 27/146

(52) U.S. Cl. CPC H01L 27/14649; H01L 27/14689; H01L 27/14685; H01L 27/14629; H01L 27/14609; H01L 27/14643; H01L 27/14623; H01L 27/14636; H01L 27/1462; H01L 27/1464; H01L 27/14625; H01L 27/14627; H01L 27/1463

(57) ABSTRACT

Implementations of image sensors may include a semiconductor layer including a photodiode, a metal layer or metal silicide layer directly coupled to a first side of the photodiode, and a storage node coupled within a second side of the photodiode. The metal layer or metal silicide layer may be configured to absorb one or more predetermined wavelengths of incident light and correspondingly heat a portion of the semiconductor layer.

### CROSS REFERENCE TO RELATED APPLICATIONS

This application is a continuation-in-part application of U.S. Utility Patent Application to Lenchenkov et al. entitled “Image Sensor with Heating Effect and Related Methods,” application Ser. No. 15/951,470, filed Apr. 12, 2018, which application is a continuation application of the earlier U.S. Utility Patent Application to Lenchenkov et al. entitled “Image Sensor with Heating Effect and Related Methods,” application Ser. No. 15/230134, filed Aug. 5, 2016, issued May 15, 2018 as U.S. Pat. No. 9,972,654, which application is a divisional application of the earlier U.S. Utility Patent Application to Lenchenkov et al. entitled “Image Sensor with Heating Effect and Related Methods,” application Ser. No. 14/723,675, filed May 28, 2015, issued Aug. 30, 2016 as U.S. Pat. No. 9,431,443, the disclosures of each of which are hereby incorporated entirely herein by reference.

### BACKGROUND

### 1. Technical Field

Aspects of this document relate generally to image sensors. More specific implementations involve complementary metal-oxide-semiconductor (CMOS) image sensors.

### 2. Background Art

Image sensors convey information related to an image by communicating signals in response to incident electromagnetic radiation. Image sensors are used in a variety of devices including smart phones, digital cameras, night vision devices, medical imagers, and many others. Semiconductor imagers utilizing charge-coupled device (CCD) and CMOS architectures exist in the art.

### SUMMARY

Implementations of image sensors may include a semiconductor layer including a photodiode, a metal layer or metal silicide layer directly coupled to a first side of the photodiode, and a storage node coupled within a second side of the photodiode. The metal layer or metal silicide layer may be configured to absorb one or more predetermined wavelengths of incident light and correspondingly heat a portion of the semiconductor layer.

Implementations of image sensors may include one, all, or any of the following:

The storage node may be configured to be shaded by the metal layer or metal silicide layer when the incident light hits the metal layer or metal silicide layer.

The image sensor may include a lens. The metal or metal silicide layer may be coupled between the lens and the semiconductor layer. The lens may be configured to direct the incident light towards either the metal or metal silicide layer.

The image sensor may include a backside integrated (BSI) sensor.

The image sensor may include an anti-reflective coating coupled to the metal or metal silicide layer.

The metal or metal silicide layer may be configured to generate electron-hole pairs in the photodiode through the heating of the portion of the photodiode.

Implementations of image sensors may include a first dielectric layer coupled over a semiconductor layer, the semiconductor layer having a photodiode. The image sensor may also include a lens coupled over the first dielectric layer, a light absorbing layer coupled over a first side of the photodiode, and a storage node coupled within a second side of the photodiode.

Implementations of image sensors may include one, all, or any of the following:

The lens may be configured to focus incident light onto the light absorbing layer.

The light absorbing layer may be configured to absorb one or more predetermined wavelengths of incident light, and correspondingly generate electron-hole pairs through heating a portion of the photodiode.

The storage node may be configured to be in a shadow of the light absorbing layer when incident light strikes the light absorbing layer.

The light absorbing layer may include tantalum.

The image sensor may include a backside integrated (BSI) sensor.

Implementations of image sensors may include a first dielectric layer coupled over a first side of a semiconductor layer, the semiconductor layer including a photodiode, a lens coupled over the first dielectric layer, an anti-reflective coating configured to allow one or more predetermined wavelengths of light to pass through the semiconductor layer, and a light absorbing layer coupled within a second side of the photodiode. The light absorbing layer may be configured to absorb one or more predetermined wavelengths of incident light and generate electron-hole pairs within the photodiode through heating a portion of the photodiode.

Implementations of image sensors may include one, all, or any of the following:

The image sensor may include a light shield layer coupled between the first dielectric layer and the semiconductor layer. The light shield layer may include an opening having the antireflective coating.

The image sensor may include a storage node included within a second side of the semiconductor layer.

The storage node may be substantially shielded from incident light by a light shield layer coupled between the first dielectric layer and the semiconductor layer.

The image sensor may include a second dielectric layer coupled to the second side of the semiconductor layer.

The image sensor may include a storage gate coupled within the second dielectric layer. The storage gate may be directly coupled to a storage node within a second side of the semiconductor layer.

The image sensor may include a transfer gate coupled within the second dielectric layer and directly coupled to the photodiode.

The light absorbing layer may include tantalum.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross section view of an implementation of an image sensor;

FIG. 2 is a cross section view of the image sensor of FIG. 1 and another implementation of an image sensor;

FIG. 3 is a cross section view of the image sensors of FIG. 2 with incident and refracted infrared (IR) light waves representatively illustrated;

FIG. 4 is a cross section view of the image sensors of FIG. 3 with temperature profiles of the image sensors representatively illustrated;

FIG. 5 is a graph plotting spectra of an imaginary part of complex refractive index for TaSi₂ and c-Si as a function of wavelength;

FIG. 6 is a graph plotting imaginary index of refraction spectra for a plurality of materials as a function of wavelength;

FIG. 7 is a cross section view of implementations of image sensors;

FIG. 8 is a cross section view of implementations of image sensors;

FIG. 9 is a cross section view of implementations of image sensors;

FIG. 10 is a cross section view of implementations of image sensors;

FIG. 11A is a cross section view of an image sensor without a light absorbing layer (between two shallow trenches on the left) next to an image sensor with a light absorbing layer (between two deep trenches on the right), illustrating incident and refracted light;

FIG. 11B is a cross section view of an image sensor with a light absorbing layer (between two shallow trenches on the left) next to an image sensor with a light absorbing layer (between two deep trenches on the right), illustrating incident and refracted light;

FIG. 12A is a cross section view of the image sensors of FIG. 11A after a specified amount of time has lapsed;

FIG. 12B is a cross section view of the image sensors of FIG. 11B after a specified amount of time has lapsed;

FIG. 13A is a cross section view of the image sensors of FIG. 12A after a specified amount of time has lapsed;

FIG. 13B is a cross section view of the image sensors of FIG. 12B after a specified amount of time has lapsed;

FIG. 14A is a cross section view of the image sensors of FIG. 13A after a specified amount of time has lapsed;

FIG. 14B is a cross section view of the image sensors of FIG. 13B after a specified amount of time has lapsed;

FIG. 15A is a cross section view of the image sensors of FIG. 14A after a specified amount of time has lapsed;

FIG. 15B is a cross section view of the image sensors of FIG. 14B after a specified amount of time has lapsed;

FIG. 16A is a cross section view of the image sensors of FIG. 15A after a specified amount of time has lapsed;

FIG. 16B is a cross section view of the image sensors of FIG. 15B after a specified amount of time has lapsed;

FIG. 17A is a cross section view of the image sensors of FIG. 16A after a specified amount of time has lapsed;

FIG. 17B is a cross section view of the image sensors of FIG. 16B after a specified amount of time has lapsed;

FIG. 18 is a top view of a dark signal (dark current) image of a printed circuit board (PCB) generated using a traditional image sensor without a light absorber layer;

FIG. 19 is a top view of another dark signal (dark current) image of a printed circuit board (PCB) generated using a traditional image sensor without a light absorber layer;

FIG. 20 is a top view of another dark signal (dark current) image of a printed circuit board (PCB) generated using a traditional image sensor without a light absorber layer;

FIG. 21 is a cross section view of another implementation of an image sensor;

FIG. 22 is a cross section view of another implementations of an image sensor;

FIG. 23 is a cross section view of an image sensor shielding a storage node with a wafer backside light shield (WBLS);

FIG. 24 is a cross section view of an image sensor similar to the image sensor of FIG. 21 shielding a storage node with the light absorbing layer; and

FIG. 25 is a chart illustrating the effectiveness of the image sensor of FIG. 24.

### DESCRIPTION

This disclosure, its aspects and implementations, are not limited to the specific components, assembly procedures or method elements disclosed herein. Many additional components, assembly procedures and/or method elements known in the art consistent with the intended image sensors and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensors and related methods, and implementing components and methods, consistent with the intended operation and methods.

As used herein, the term “image sensor” may refer both to a sensor associated with only an individual pixel as well as to a sensor associated with a plurality (such as an array) of pixels. As used herein, the term “backside” refers to a side (in other words a surface) of an element corresponding with (in other words, located at, or facing) a wafer backside during fabrication. As used herein, the term “frontside” refers to a side (in other words, a surface) of an element corresponding with (in other words, located at, or facing) a wafer frontside during fabrication.

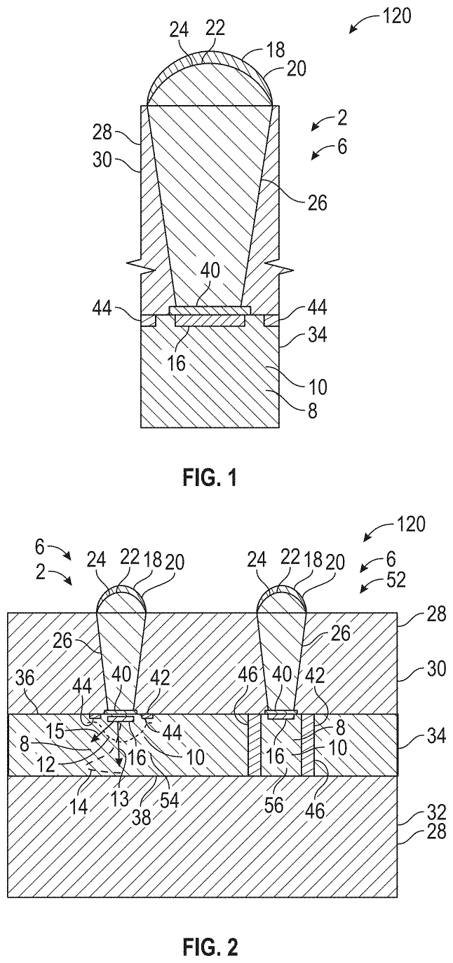

Referring now to FIGS. 1-2, in various implementations an image sensor (sensor) 2 is formed as a backside integrated (BSI) sensor 6 or, in other words, it is formed adjacent a wafer backside during fabrication. Image sensor 2 includes a photodiode 8 associated with a single pixel 10. Trenches 42 are used for isolation purposes—in this case primarily for heat isolation, as is discussed herein. Shallow trenches 44 are used with the leftmost image sensor 2 shown in FIG. 2 and deep trenches 46 are shown with the rightmost image sensor 52 shown in FIG. 2.

In FIGS. 1-2 a semiconductor layer 34 is sandwiched between two dielectric layers 28. The dielectric layers may be intermetal dielectric (IMD) or interlayer dielectric layers (ILD). The semiconductor layer in this representative example is a silicon layer and the dielectric layers are silicon dioxide (SiO₂) layers. The trenches in the examples shown in the drawings are formed with SiO₂ as well. One of the dielectric layers is a frontside dielectric layer 32 which corresponds with (or in other words is located at) a wafer frontside during fabrication. The other dielectric layer is a backside dielectric layer 30 which corresponds with (or in other words is located at) a wafer backside during fabrication. The semiconductor layer thus has a backside surface 36 which faces (or is located at or on) the wafer backside and a frontside surface 38 which faces (or is located at or on) the wafer frontside during fabrication. The frontside dielectric layer is coupled with the frontside surface of the semiconductor layer and the backside dielectric layer is coupled with the backside surface of the semiconductor layer.

Although silicon-based semiconductor layers and dielectric layers are used in the representative examples, in other implementations non-silicon-based semiconductor layers and/or dielectric layers could be used as well. The elements of image sensors disclosed herein, however, may be useful to allow the formation of infrared (IR) sensors using silicon-based semiconductor layers, which layers in and of themselves are generally incapable of IR sensing due to the bandgap properties of silicon. However, various image sensor implementations may be utilized to detect visible and human invisible light (i.e., ultraviolet, etc.) and any combination of visible and human invisible light.

In FIG. 2 there are two pixels 10 shown, a first pixel 54 and a second pixel 56. Such pixels may naturally be arranged in a line, in an array, or in any other arrangement in order to achieve an image sensor having a plurality of pixels arranged according to any desired configuration.

Each photodiode/pixel is associated with, or includes, a photodiode depletion region 14. The photodiode depletion region 14 is generally located in a plane perpendicular with the page and is represented by the dashed line shown, having a maximum voltage (such as a pin voltage of a semiconductor device including the image sensor(s), or V_{PIN}) at the frontside surface 38. A photodiode depletion potential 12, represented in the plane of the page by the other dashed line shown, with a barrier shown at approximately the p-well region, is associated with each pixel. When an event occurs sufficient to create electron/hole pairs, an electron flow 13 and a hole flow 15 are produced, and are representatively depicted by the arrows shown, thus providing a current to produce a signal associated with the pixel, as separated electrons are collected by the photodiode depletion field of the pixel.

A lens 22 and/or a light guide 26 may be included to refract, focus and/or otherwise convey light towards the pixel. Lens 22 in implementations is a silicon nitride (SiN) microlens 24. In other implementations, the light guide 26/lens 22 may each be made of, by non-limiting example, Si, TiO₂, SiC or any other high index and non-light absorbing material that has a low thermal conductivity relative to materials such as metals. The light guide 26 is generally housed or situated within the backside dielectric layer 30. An antireflective coating (ARC) 40 is included which reduces the percentage of light that is reflected back out of the light guide away from the pixel. An antireflective coating (ARC) 18 is also placed atop the lens 22 to reduce the amount of light that is reflected back upwards at the lens surface. In implementations ARC 40 is formed of silicon dioxide (SiO₂). In other implementations ARC 40 could be formed of SiN, SiC, TiO₂, polycrystalline Si (poly-Si), amorphous Si (a-Si), or another material. In implementations the lens may be formed as a bump and the ARC 18 may be formed as a coating on the bump. In implementations in which the lens is a bump it may be formed of the same material as the light guide and both could be formed of one continuous element with no surfaces therebetween.

The elements described thus far may be used to sense light within given wavelengths. When the wavelength of light entering the lens/light guide is configured to create electron/hole pairs in the semiconductor layer due to the characteristic band gap of the semiconductor material, a current will be produced and the light will be sensed, or, in other words, the light may be used to create a signal representative of the light. Some wavelengths of light may be unable to produce a signal based on the band gap of the semiconductor material. For example, some or all infrared (IR) wavelengths generally will pass through a semiconductor layer made of silicon without producing such a signal due to the specific band gap of silicon.

In implementations of an image sensor 2/52, a light absorber layer 16 is placed at the backside surface 36 and corresponds with the bottom of the light guide. In the example shown in FIGS. 1-2 the light absorber layer has the ARC 40 placed atop it. The light absorber layer is configured to absorb light of a predetermined wavelength. In the representative examples shown in the drawings, the light absorber layer is specifically tailored to absorb light in the infrared (IR) region, though in other implementations it could be tailored to absorb light in any other spectral regions of light, whether human visible or not. The light absorber layer is formed of a material that is configured to absorb photon energy of incident light and convert the photon energy into heat. The generated heat then creates/facilitates creating electron/hole pairs to provide the current that is used to provide a signal and therefore sense the light. This process by which the light absorber layer absorbs light and generates heat to the pixel structure beneath it can be referred to as photo-thermally coupling the light absorber layer with the pixel.

In implementations the light absorber layer includes an electrically conductive material (conductor). In implementations the light absorber layer includes one or more of the following materials: Co; CoSi₂; Mo; MoSi₂, Ni; NiSi; Ni₂Si; NiSi₂, Pd; PdSi; Pd₂Si; Pt; PtSi; Ta; TaSi₂, Ti; TiSi₂, W; WSi; WSi₂; Zr; ZrSi₂; polycrystalline Si; Ge doped monocrystalline Si; Ge film on Ge doped silicon; GeSe film on Silicon; and/or any combination thereof. Many other materials may be used for sensing IR light so long as they have high absorption for lower frequencies of light. In implementations in which the light absorber layer is a metal silicide and the semiconductor layer is a silicon-based semiconductor (such as monocrystalline or polycrystalline silicon), the metal silicide may act as a perfect or near perfect electronic-vibrational heat transfer bridge between the metal and the silicon, and may ensure a fast (or the fastest) local heat transfer rate into the pixel. In various implementations, the light absorber layer may be referred to as including one or more narrow band semiconductors or conductors which act as highly efficient absorbers of incident radiation and converters of the absorbed energy to heat localized beneath the layer. The semiconductor layer may be referred to as a broad band semiconductor that contains a pixel depletion region. This pixel depletion region is a region with a built-in depletion field configured to separate electron-hole pairs formed inside or at the boundary of the depletion region of a given pixel at the location of the interface of the light absorber layer and the semiconductor layer. The heat generated by the light absorber layer, as discussed herein, generates electron-hole pairs in the pixel depletion region.

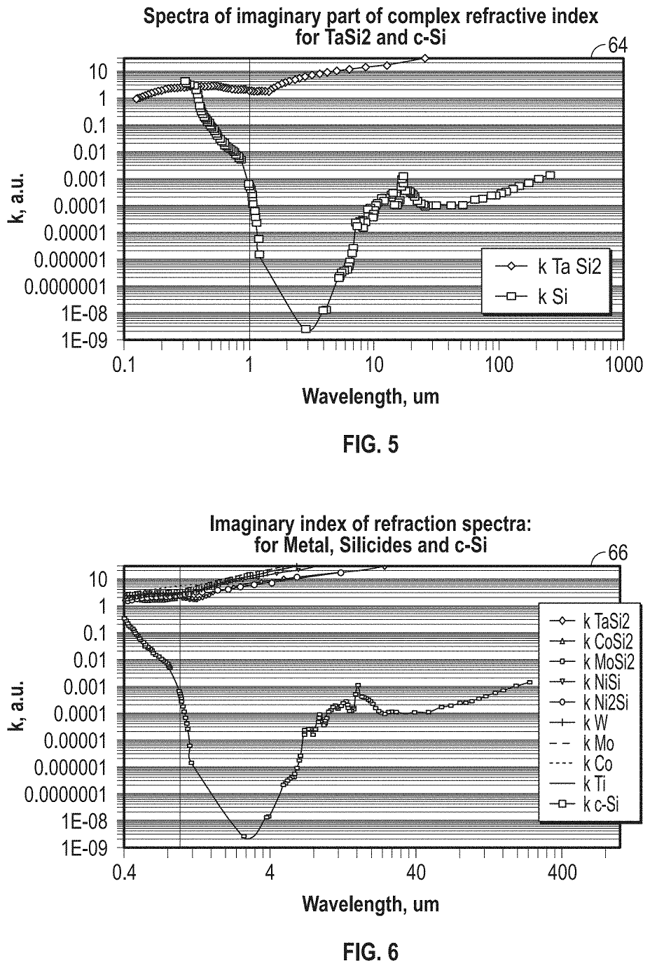

A material's ability to function well as material for a light absorber layer may be predictable using the imaginary part of the complex index of refraction—a higher “k” value corresponds to higher absorption values. For example, FIG. 5 shows a graph 64 which plots exponential k values for TaSi₂ and monocrystalline Si (c-Si) against spectral wavelength. A formula for determining absorption is: Absorption=1−exp(−4πkd/λ); where d=thickness, λ=wavelength and k=the imaginary part of the refractive index.

From FIG. 5 it can be seen that 100% absorption in very thin TaSi₂ happens in a very wide spectral range, about 10 to 100 times wider than in monocrystalline silicon. This predicts that an image sensor for wide range IR sensing may be formed with one or more wide range IR sensitive pixels using a thin TaSi₂ layer as the light absorber layer. This may be formed as a BSI sensor. FIG. 6 shows a graph 66 which plots exponential k values for a few metals, metal silicides (namely, TaSi₂, CoSi₂, MoSi₂, NiSi, Ni₂Si, W, Mo, Co, and Ti), and monocrystalline Si (c-Si) against light wavelength. Each metal and silicide plotted exhibits an exponential absorption coefficient at least about 100-1,000 times higher than that in monocrystalline Si and would allow the detection of photons in a much wider spectral range—at least 100 times greater—than monocrystalline Si. The differences in absorption coefficient shows significant predominance in conductor density of states (DOS) at the low frequency portion of the spectra responsible for fast, efficient heat transfer—thus equating to a very fast, localized heating effect in a pixel. The k value is directly related to DOS and is often used in spectroscopy to estimate DOS.

Thus, the light absorber layer in implementations may include a highly absorptive, non-reflective (or low-reflective) thin layer conductor at the back side integrated (BSI) side of a complementary metal-oxide-semiconductor (CMOS) or CCD image sensor pixel to generate a fast localized heating effect of the semiconductor material (such as Si) for greater electron/hole generation in the pixel/photodiode depletion region. Spreading the light absorber layer laterally above, near or within the pixel photodiode depletion region (and/or centering the light absorber layer relative to the pixel) localizes heat for increased electron/hole pair generation at or near the interface of the light absorber layer with the semiconductor layer. Generated electron/hole pairs are separated and signal electrons are collected using the photodiode depletion field 12.

Energy from the absorbed photons is very quickly converted into non-equilibrated pixel-localized heat. This absorption/conversion may likely occur within a few picoseconds which is much faster than lateral heat dissipation in Si via phonons (approximately 10-15 THz). FIGS. 18-20 show experimental observations in which even slower resistive heating rates on the order of GHz generate laterally well-defined signals (as “dark current” or “dark signal” images) from printed circuit boards of traditional image sensor pixel arrays. Thus “dark current” or “dark signal” which is exhibited in traditional image sensors is unintentionally captured, but with the image sensors 2, 52 disclosed herein, such dark current will be captured intentionally by absorption of lower than Si bandgap photons in a light absorber layer. Accordingly, the image sensors utilizing light absorber layers allow the imaging of long wavelengths of light even when these are outside of the Si bandgap. Upon absorption of IR photons with frequencies of about 30-500 THz (wavelengths of 10-0.6 micrometers) the increased local heating in the pixel will resulting in increased electron-hole pair generation compared with the aforementioned process related to traditional image sensors.

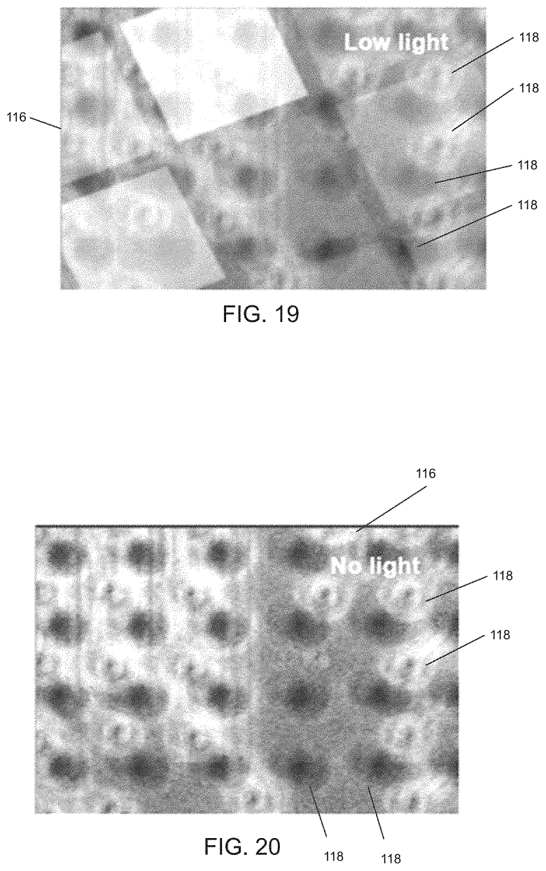

FIG. 18 shows a printed circuit board (PCB) 112 of a traditional image sensor, the PCB having metal routing 114 giving off a “dark signal” from resistive heating that is captured by the image sensor. FIGS. 19-20 show a printed circuit board (PCB) 116 of another traditional image sensor with contact balls 118 formed of tungsten, the contact balls giving off a “dark signal” as captured by the traditional image sensor. As indicated on the images, FIG. 19 is a low light capture (i.e., low irradiation of the image sensor) and FIG. 20 is a no light capture (i.e., no irradiation of the image sensor). In each of these cases the dark signal is generated due to resistive heating of the elements of the image sensor (or the PCB of the image sensor or a PCB coupled with the image sensor). Thus, resistive heating of the metal routing in FIG. 18 and resistive heating of the contact balls in FIGS. 19-20 creates the dark signals shown in the images. FIG. 18 was captured with a front side illuminated sensor. FIGS. 19-20 were obtained at 70 degrees Celsius and reveal a non-uniformity among the contact balls. Such dark signals have also been captured in BSI image sensor arrays from resistively heated TiN plugs.

In the above cases of FIGS. 18-20 the dark signal is produced by a resistively heated conductor at the conductor/semiconductor (i.e., conductor/Si) interface. In these cases wavelengths longer than the maximum wavelength for monocrystalline silicon (which is approximately 1.2 microns), are detected as dark signals. FIG. 18 is a traditional front side image sensor producing a dark signal either though resistive heating of the PCB routings or through long wavelength absorption. In implementations the image sensors 2, 52 and others disclosed herein could be configured to detect dark signals of a PCB or other element coupled with the image sensor that create a “constant” dark image (noise) during use and to automatically correct for them.

In the image sensors 2, 52 and others disclosed herein, the light absorber layer placed at the BSI side of the semiconductor layer (such as Si) in a BSI CMOS image sensor pixel enhances and extends the sensing capability of a light sensor beyond the Si band gap to long light wavelengths in the spectral range of about 0.7 to 20 microns.

In the implementations shown in FIGS. 1-2 the image sensors 2/52 are complementary metal-oxide-semiconductor (CMOS) sensors 120, though other types of devices could be used to form the image sensors 2/52 such as charge-coupled device (CCD) sensors. When a CMOS sensor 120 is used, the device becomes an enhanced IR sensitive BSI CMOS image sensor which uses a local photon heating effect.

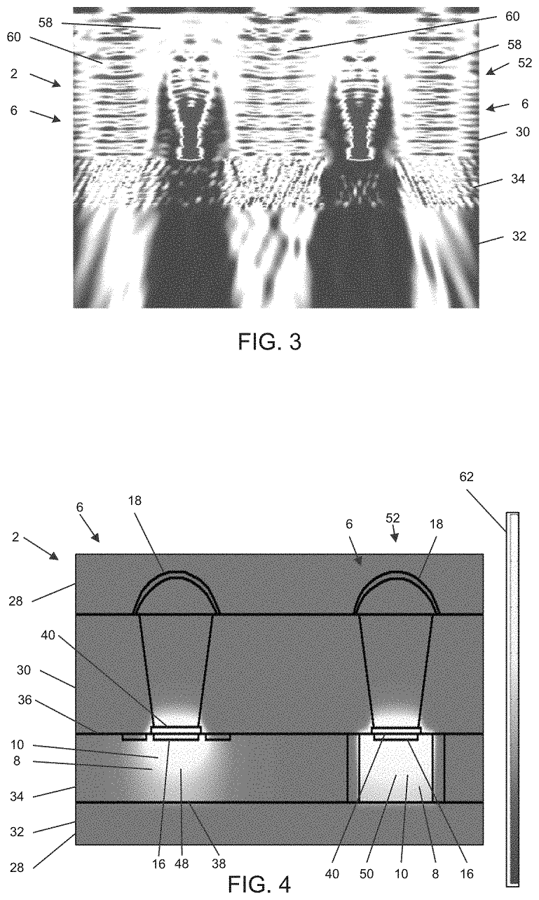

FIG. 3 is an image produced using a nanophotonic modeling software sold under the trade name FDTD SOLUTIONS by Lumerical Solutions, Inc. of Vancouver, Canada. Variables used in the model were optimized to achieve above 60% theoretical quantum efficiency (QE) and include, among others, the following parameters (which may also be used in actual implementations of image sensors): the image sensor is a BSI sensor; the incident light is a 1500 nanometer (nm) wavelength plane wave of light; lens 22 has a radius of curvature of 1860 nm and a height of 640 nm and is made of SiN; ARC 18 is an SiO₂ ARC 20 and is 200 nm thick; the semiconductor layer 34 is 2 micron thick silicon; the pixel width/diameter is 3 microns; the light absorber layer is a 160 nm thick TaSi₂ layer; the light guide is formed of SiN having an entrance diameter DIN of 1500 nm, an exit diameter DOUT of 260 nm and a length from DIN to DOUT of 3280 nm; the area/volume above the backside dielectric layer is air; the ARC 40 is a 110 nm by 1800 nm SiC layer (n=2.6; k=0); the backside dielectric layer is, or is about, 3-4 microns thick and is formed of SiO₂; the frontside dielectric layer is, or is about, 4 microns thick and is formed of SiO₂, and; the shallow and deep trenches are formed of SiO₂.

Not all of the elements of FIG. 2 are specifically pointed out in FIG. 3, but the reader can envision where the various elements would be located if the two images were superimposed. The backside dielectric layer 30, semiconductor layer 34 and frontside dielectric layer 32 are indicated, and the position of the image sensors 2 and 52 are generally pointed to and their locations are evident from the light profile and from the previous FIG. 2 which has the same configuration for the various elements. As can be seen from the image in FIG. 3 produced by the modeling software, the incident light 58, which in this case is infrared (IR) light 60, is irradiated towards two image sensors, an image sensor 2 and an image sensor 52, both of which are backside image sensors 6, but image sensor 2 has the shallow trench configuration while image sensor 52 has the deep trench configuration as discussed herein. The model shows a high intensity of the incident 1500 nm wavelength light before it hits the SiC/TaSi₂ interface.

The optical simulation shows intensity distribution of the 1500 nm light. With respect to the left hand image sensor 2, none of the 1500 nm light is passing through the TaSi₂ layer, and this results in a pixel quantum efficiency (QE) of 62%, assuming that 100% of absorbed photon energy is converted into un-equilibrated heat within the TaSi₂ light absorber layer 16. The model also shows little or zero absorption of 1500 nm light in the silicon semiconductor layer, as the light intensity appears unchanged in the regions where the infrared light passes into and through the silicon layer. The right hand image sensor 52 appears to show similar properties. The two image sensors 2 and 52 appear to behave generally identically notwithstanding the deep trench configuration of image sensor 52 and the shallow trench configuration of image sensor 2. The region through which the 1500 nm light is blocked may be marginally or negligibly larger for the image sensor 52 but, in general, isolation choice does not appear to impact optical characteristics at 1500 nm.

The models above indicate that image sensors including the elements described herein may achieve a very high sensitivity (above 50% quantum efficiency (QE)) of infrared photons in a very wide spectral range including 0.7 to 20 micron wavelengths (beyond the Si band gap).

FIG. 4 shows an image created with a modeling software sold under the trade name COMSOL MULTIPHYSICS by COMSOL, Inc. of Burlington, Mass. and using the same parameters as those described above with respect to the FDTD SOLUTIONS model. The image shows temperature distribution 20 nanoseconds after absorption of an incident 1500 nm light wave by the light absorber layer. A heat scale 62 is shown and ranges from 24 degrees Celsius (dark end) to 40 degrees Celsius (light end), and corresponding colors in FIG. 3 therefore illustrate the temperature distribution. As can be seen, lateral heat dissipation is relatively slow. The heat is fairly localized at 20 ns for both the light sensor on the left with shallow trench isolation (shown by heated region 48) and the light sensor on the right with deep trench isolation (shown by heated region 50). The heat is generally confined to the pixel area in both cases. The light sensor with deep trench isolation on the right, however, shows a substantially improved confinement of the heat to within the pixel active area, thus increasing its temperature higher and improving its quantum efficiency (QE). This model assumes that 100% of the absorbed 1500 nm photon energy is converted into non-equilibrated localized heat within the pixel. Pixel quantum efficiency (QE) at 1500 nm according to the model is 62%.

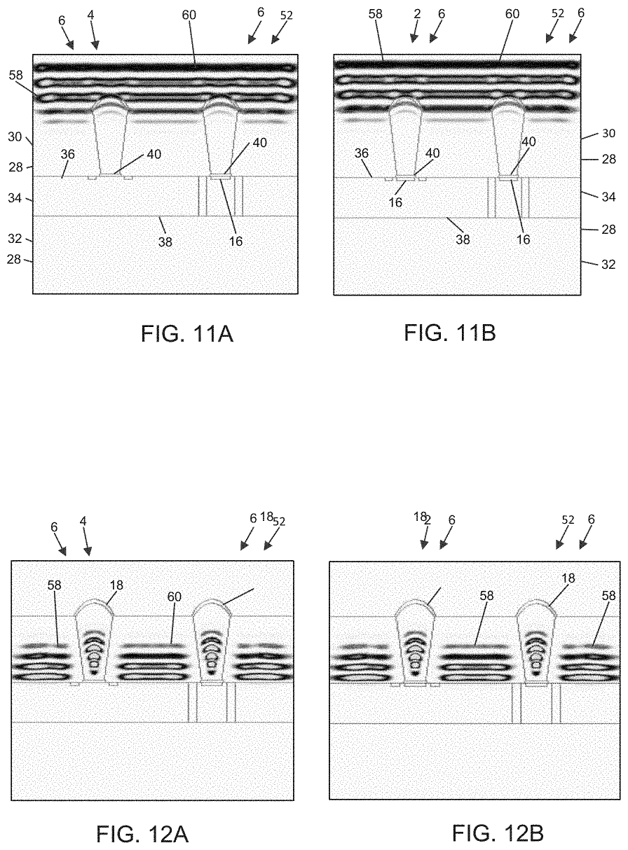

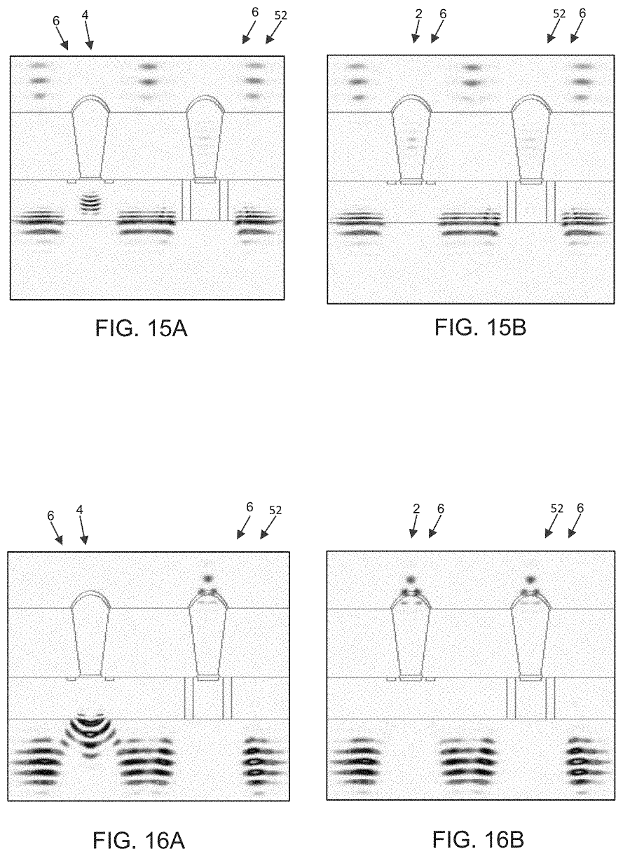

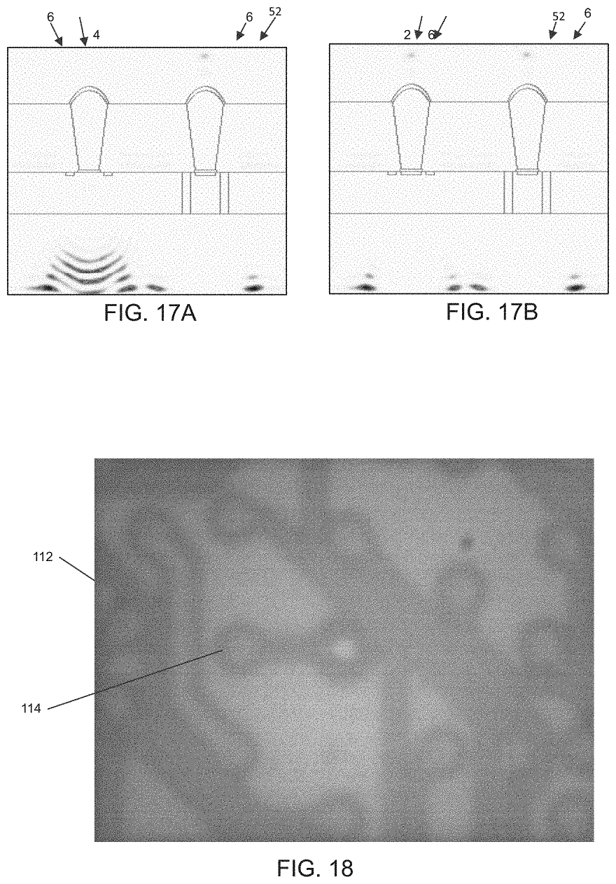

FIGS. 11A-17B show modeled time lapse images showing absorption, reflection, refraction, and pass-through of a pulse of 1500 nm light using the same variables as discussed above. FIGS. 11A, 12A, 13A, 14A, 15A, 16A, and 17A show versions where the left hand image sensor 4 does not include a light absorber layer and includes shallow trench isolation, while the right hand image does include a light absorber layer and includes deep trench isolation. In FIGS. 11B, 12B, 13B, 14B, 15B, 16B and 17B, the variables are exactly similar except that the left hand image sensor does include a light absorber layer.

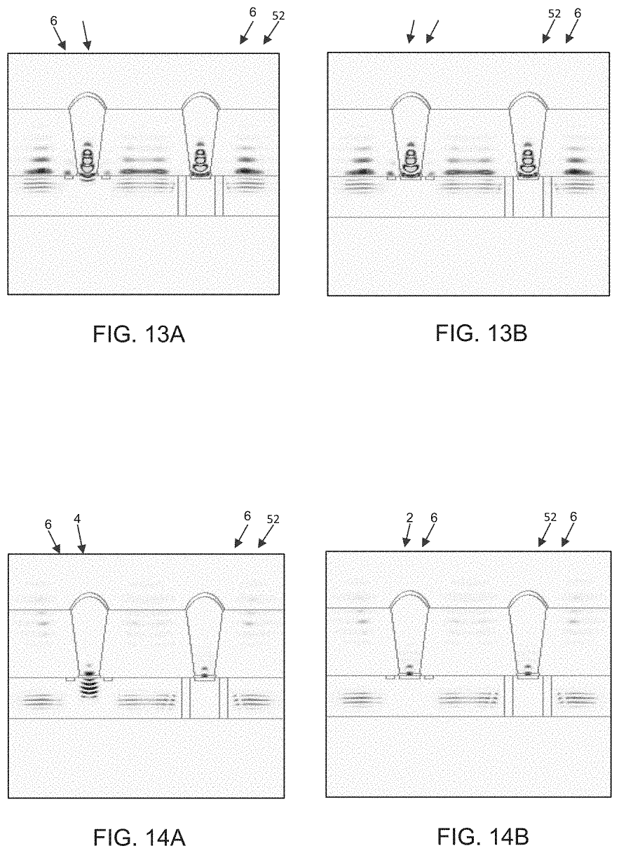

In FIGS. 11A and 11B the incident light 58, which in this model is infrared (IR) light 60 of 1500 nm, has begun to pass through the backside dielectric layer on the sides of the light guides and to be refracted (focused) by the lenses and light guides. In FIGS. 12A and 12B the passing of the light through the backside dielectric layer is further seen as well as further refraction/focusing by the light guides. In FIGS. 13A and 13B the light on the sides of the light guides is seen partially passing through the semiconductor layer and partially being reflected, while the light within the light guides in every case is seen as being further refracted/focused and being fully absorbed by the light absorber layers—except with regards to image sensor 4 wherein the light is seen passing straight through the light guide into the semiconductor layer. This generally continues with the remaining FIGS. 14A-17B—the light is shown to pass straight through image sensor 4 and into the semiconductor layer, through the semiconductor layer to the frontside dielectric layer, and so forth. There is some refraction seen at each layer.

Thus, the modeled images of FIGS. 11A-17B show generally what would be expected in light of the continuous irradiation model of FIG. 3, namely, none of the incident 1500 nm light pulse passes through the light absorption layers, but the image sensor 4 without a light absorber layer allows the light to pass straight through it and out into the semiconductor layer, and out of the semiconductor layer into the frontside dielectric layer. Image sensor 4 accordingly does not “sense” the infrared light pulse, as is the case with traditional silicon-based image sensors in general.

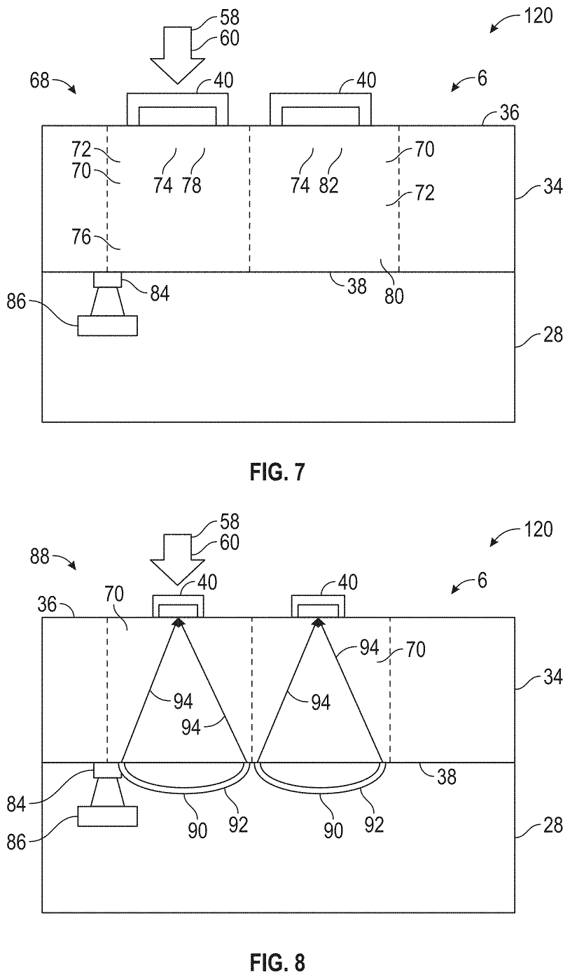

FIG. 7 shows an image sensor (sensor) 68 which includes a pair of photodiodes 70, each including a pixel 72 having a depletion region 74. First pixel 76 has a first depletion region (PD region) 78 and second pixel 80 has a second depletion region (PD region) 82. The light absorber layers are seen between the backside surface 36 and the ARC 40. A transfer gate 84 electrically couples the separated electrons with electrical routing 86 which is at least partially within the shown dielectric layer 28, which is a frontside dielectric layer. In this version there is no backside dielectric layer shown. The backside dielectric layer may be excluded, though in implementations there may be a backside dielectric layer which partially encapsulates the sides of the ARC 40 except at least for their top sides, as can be imagined. The electrical routing 86 may electrically couple the photodiode to another element of the image sensor such as an amplifier, a processor, a memory element, and so forth. The electrical routing may additionally or alternatively couple the photodiode with any element outside of (or external to) the image sensor, such as an amplifier, a processor, a memory element, and so forth.

Notably, the image sensor(s) of FIG. 7 do not include any lenses or light guides, but the light absorber layer is located directly on the semiconductor layer and the ARC 40 is located directly on top of the light absorber layer. Thus, this version does not include any focusing or light guiding elements. This architecture could be used in BSI image CCD and CMOS image sensors, and may not require focusing elements especially in longer than max c-Si detection wavelength (i.e., larger than approximately 1.2 microns).

FIG. 8 shows an image sensor 88 that is identical to image sensor 68 except that a focusing element 90 is included within the frontside dielectric. Focusing element 90 is a reflector 92 and reflected light waves 94 of the incident light 58 are shown being directed towards the light absorber layer(s) thereby. Thus this image sensor includes a frontside reflecting focusing element which focuses the incident light towards a light absorber layer at the BSI side. In implementations the focusing element 90 is a metal reflector or a multilayer dielectric reflector.

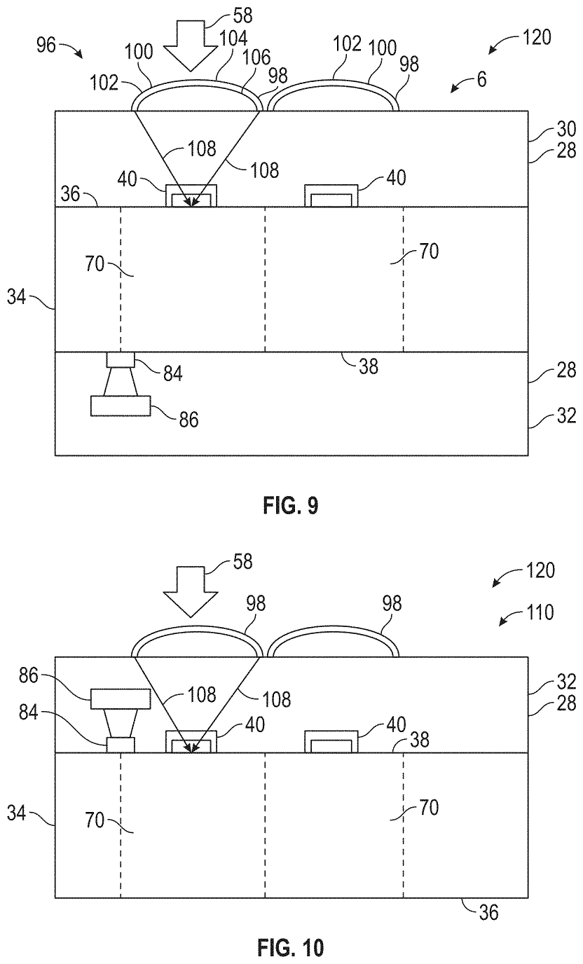

FIG. 9 shows an image sensor 96 which is similar to image sensor 68 except including a backside dielectric layer 30 and a focusing element 98, which is a lens 100. The lens 100 may be a microlens 102 which may simply be a bump 106 in the dielectric material and may have an antireflective coating 104 placed thereon. The bump may be formed of the same material as the backside dielectric layer and may have a refractive index greater than 1. In implementations the antireflective coating may be omitted. Refracted light 108 is shown being directed towards the light absorber material where it is absorbed.

Image sensor 110 of FIG. 10 is identical to image sensor 96 except that it is a frontside device, with the light absorber material located at the frontside surface 38 of the semiconductor layer, and with the transfer gate 84 and electrical routing 86 located within the frontside dielectric layer 32. This image sensor may particularly be an option where larger pixels are used. In such implementations, the architecture may be designed so as to avoid illuminating metal routings with the incident light.

Some implementations of image sensors implemented using components disclosed herein may allow spectral collection in an extremely wide range (up to very long wavelengths in the far infrared (IR) range greater than 20 microns). For optimal conditions for any particular spectral range the choice of material for the light absorber layer and its thickness, as well as materials and sizes for the antireflective coatings, lenses, light guides, semiconductor layers, dielectric layers, and so forth, may be varied and or developed, and related changes in process flows may be undertaken as well.

In some implementations of image sensors some photons may be released from the light absorber layer from the light absorber layer itself being heated, but the amount of photons may be small or negligible relative to the incident light.

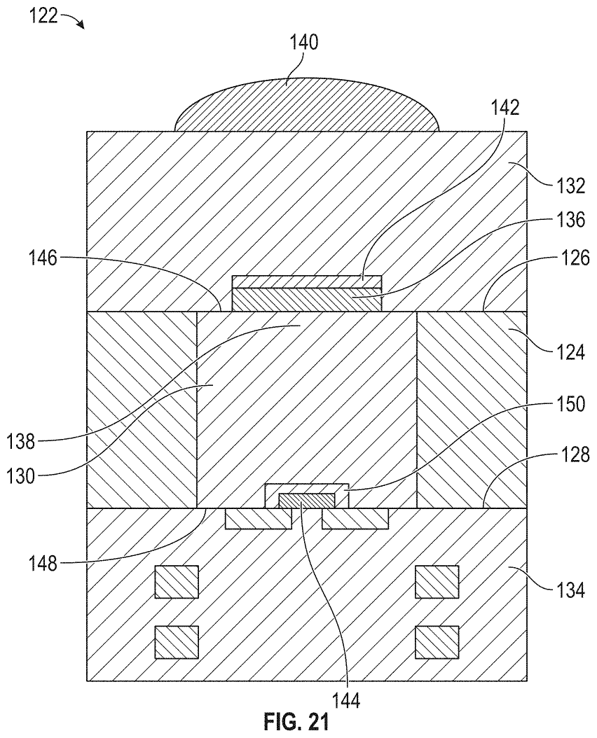

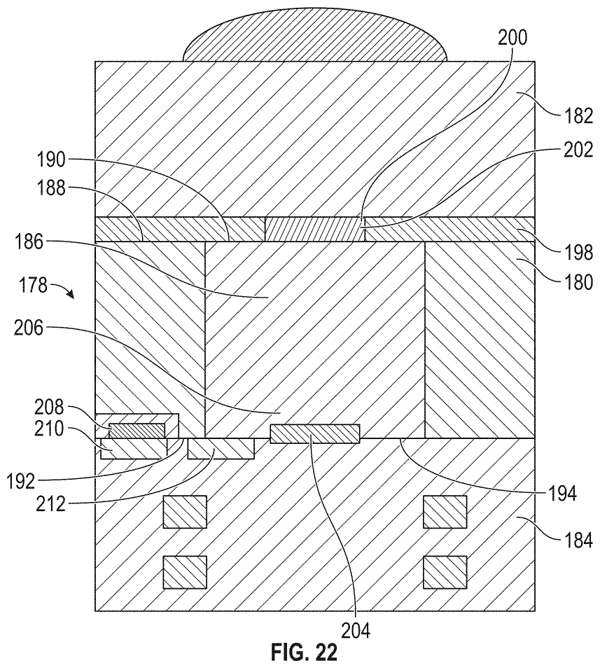

Referring to FIG. 21, another implementation of an image sensor is illustrated. In various implementations, the image sensor 122 may be a BSI image sensor. The implementation illustrated by FIG. 21 may be similar to the implementation illustrated by FIG. 1. As illustrated, the image sensor 122 include a semiconductor layer 124 having a first side 126 and a second side 128 opposite the first side. In various implementations, the first side 126 may correspond with a backside of a wafer and the second side 128 may correspond to a front side of a wafer. The semiconductor layer 124 may be any type of semiconductor layer disclosed herein. The semiconductor layer 124 includes a photodiode 130, which may be the same as or similar to any photodiode disclosed herein. The photodiode 130 includes a first side 146 corresponding to the first side 126 of the semiconductor layer 124 and a second side 148 corresponding to the second side 128 of the semiconductor layer.

Similar to other implementations disclosed herein, the image sensor 122 may include a first dielectric layer 132 coupled to the first side 126 of the semiconductor layer and a second dielectric layer 134 coupled to the second side 128 of the semiconductor layer 124. As illustrated by FIG. 21, the image sensor 122 includes a light absorbing layer 136 coupled over the photodiode 130. In various implementations, the light absorbing layer 136 may be within the first dielectric layer 132 and may be directly coupled to the first side 126 of the semiconductor layer 124. In other implementations, the light absorbing layer 136 may be within the photodiode 130 and the first side 126 of the semiconductor layer 124. In various implementations, the light absorbing layer 136 may be a continuous layer and may span the entire width of the photodiode 130. In other implementations, as illustrated by FIG. 21, the light absorbing layer 136 may be a continuous layer but may not span the entire width of the photodiode 130. In such implementations, the light absorbing layer 136 may be considered a floating light absorbing layer. In various implementations, as illustrated by FIG. 21, the light absorbing layer 136 may be centered over the photodiode 130.

In various implementations the light absorbing layer 136 may include a metal or a metal silicide. In particular implementations the light absorbing layer may include, by non-limiting example, tungsten, tungsten silicide, cobalt, cobalt silicide, tantalum, tantalum silicide, or any other material disclosed herein.

Like the image sensor of FIG. 1, the light absorbing layer 136 absorbs some or all of one or more predetermined wavelengths of incident light and correspondingly heats a portion 138 of the semiconductor layer 124 or photodiode 130. As the portion 138 (including the interface between the light absorbing layer 136 and the photodiode 130) is heated, electron-hole pairs are generated within the photodiode in a similar manner to the implementations illustrated by FIGS. 1-2. When an event occurs sufficient to create electron/hole pairs, an electron flow and a hole flow are produced, thus providing a current to capable of being used to generate a signal associated with the pixel.

Still referring to FIG. 21, in various implementations the image sensor includes a lens 140 coupled over the first dielectric layer 132 such that the light absorbing layer 136 is coupled between the lens 140 and the semiconductor layer 124. A lens 140 may be included to refract, focus and/or otherwise convey light towards the light absorbing layer 136. Lens 140 in various implementations is a silicon nitride (SiN) microlens. In other implementations, the lens 140 may be made of, by non-limiting example, Si, TiO₂, SiC or any other high index and non-light absorbing material that has a low thermal conductivity relative to materials such as metals. While not illustrated by FIG. 21, in various implementations, the image sensor may include a light guide which may be the same as or similar to the light guide 26 of FIG. 1.

In various implementations the image sensor 122 may include an ARC 142 coupled over the light absorbing layer 136. In various implementations, though not illustrated, an ARC may also be coupled directly to the lens 140 to reduce the amount of light that is reflected back upwards at the lens surface. In implementations ARC 142 may include any materials of any other ARCs disclosed herein.

In various implementations the semiconductor layer 124 of image sensor 122 may include deep or shallow trenches such as the trenches illustrated by FIG. 2. In other implementations, the image sensor 122 may not include any trenches.

Still referring to FIG. 21, in various implementations the image sensor 122 includes a storage node 144 coupled within the second side 148 of the photodiode 130. The storage node 144 may be isolated from the rest of the photodiode 130 through a storage node barrier 150. The storage node is shaded by the light absorbing layer when incident light hits the light absorbing layer. In this manner, the light absorbing layer 136 has a dual functionality as it serves as a light shield for the storage node 144 located at the second side 148 of the photodiode 130 and also acts as the heating element, used to generate a signal, on the first side 146 of the photodiode.

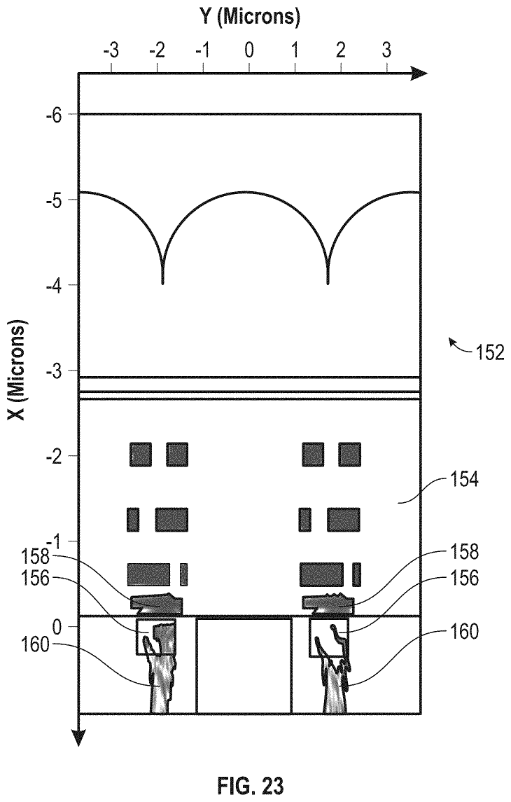

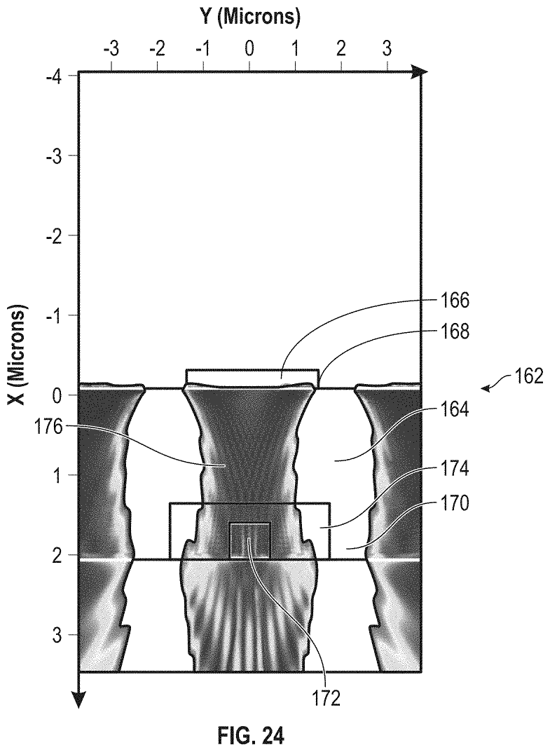

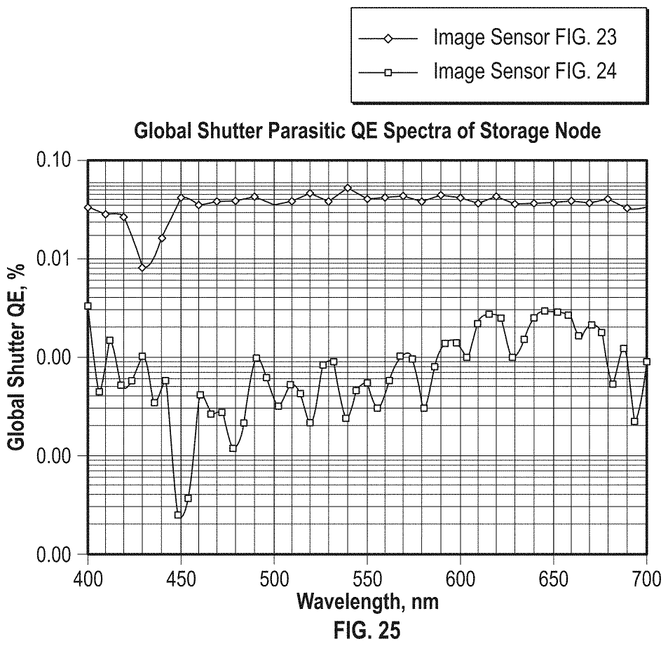

The light absorbing layer's capacity to act as a light shield is illustrated by FIGS. 23-24. Referring to FIG. 23, a cross section view of a simulation of an image sensor shielding a storage node with a wafer backside light shield (WBLS) is illustrated. The image sensor 152 of FIG. 23 is a WBLS global shutter pixel. The image sensor 152 includes a photodiode 154 with two storage nodes 156 isolated below the photodiode 154. The image sensor includes a WBLS 158 over each of the storage nodes 156. Shaded areas 160 are representative of areas where a particular wavelength of incident light is shielded (which may be, in this particular case, light having a wavelength of 509 nm). Further, the darkness of the shade is representative of how much of the particular wavelengths of incident light are blocked, with the darker shade representing a greater amount of incident light blocked. As illustrated by FIG. 23, the WBLS 158 in the global shutter pixel image sensor still allows a significant amount of a particular wavelength of light (509 nm) to enter into the storage nodes 156.

In contrast to FIG. 23, FIG. 24 is a cross section view of a simulation of an image sensor similar to the image sensor of FIG. 21 shielding a storage node with a light absorbing layer. Like the image sensor of FIG. 21, image sensor 162 includes a photodiode 164. A light absorbing layer 166 is coupled to the first side 168 of the photodiode 164. The photodiode 164 also includes a storage node 172 at the second side 170 of the photodiode. The storage node 172 is shielded from the remainder of the photodiode through the storage node barrier 174. The shaded areas 176 of FIG. 24 are representative of how much of the particular wavelength of incident light (in this case, wavelengths of 509 nm) are blocked, with the darker shade representing a greater amount of incident light blocked. As is illustrated by FIG. 24, the storage node 172 is shielded from light having a wavelength of 509 nm much better than the storage nodes 156 of FIG. 23. In particular implementations, the storage node 172 may receive as much as 100 times less the amount of a predetermined wavelength of light than the storage nodes 156 of FIG. 23.

Referring to FIG. 25, a chart illustrating the effectiveness of the image sensor of FIG. 21 is shown. The chart of FIG. 25 illustrates the global shutter parasitic QE spectra of the storage nodes 156 of FIG. 23 as compared to the storage node 172 of FIG. 24. As illustrated, the QE, measured as a percentage, is less for the image sensor of FIG. 24. Accordingly, the efficiency of the image sensor of FIG. 24 is greater than the efficiency of the image sensor of FIG. 23. In a particular example, the efficiency of the image sensor of FIG. 23 may be approximately 64 dB and the efficiency of the image sensor of FIG. 24 may be approximately 104 dB.

In addition to having a greater efficiency, the image sensor of FIGS. 21 and 24 may also achieve a greater pixel sensitivity. In various implementations, the image sensor of FIG. 23 may be unable to detect wavelengths greater than 1100 nm. In implementations having the light absorbing layer, the pixel sensitivity of the image sensor may be extended beyond 1100 nm (for example, the image sensor may be able to detect wavelengths of 1550 nm).

Referring to FIG. 22, another implementation of an image sensor is illustrated. The image sensor 178 is similar to the image sensor of FIG. 21 inasmuch as it includes a semiconductor layer 180 having a photodiode 186 and coupled between a first dielectric layer 182 and a second dielectric layer 184. The first dielectric layer 182 may be coupled to the first side 188 of the semiconductor layer and to the first side 190 of the photodiode 186. The second dielectric layer 184 may be directly coupled to the second side 192 of the semiconductor layer 180 and to the second side 194 of the photodiode 186. In various implementations, the image sensor 178 may also include a lens 196 coupled over the first dielectric layer 182. The lens 196 may be similar to or the same as any type of lens disclosed herein.

In various implementations, the image sensor 178 includes a light shield layer 198 coupled between the first dielectric layer 182 and the semiconductor layer 180. The light shield layer 198. As illustrated by FIG. 22, the light shield layer 198 may include an opening 200 configured to allow incident light to enter the photodiode 186. In various implementations, the image sensor 178 may include an ARC 202 within the opening 200. The ARC 202 may be configured to allow one or more predetermined wavelengths of light to pass through the semiconductor layer 180.

Still referring to FIG. 22, the image sensor includes a light absorbing layer 204 coupled in the second side 194 (which may be the front side) of the photodiode 186. The light absorbing layer may include the same material as any other light absorbing layer disclosed herein. The light absorbing layer 204, like the light absorbing layer of FIG. 21, is configured to absorb one or more predetermined wavelengths of incident light and generate electron-hole pairs within the photodiode 186 through heating a portion 206 of the photodiode. As the portion 206 (including the interface between the light absorbing layer 204 and the photodiode 186) is heated, electron-hole pairs are generated within the photodiode in a similar manner to the implementations illustrated by FIGS. 1-2 and 21. More specifically, due to the localized and fast photon absorption heating effect, electron-hole pairs are generated at the interface between the light absorbing layer 204 and the photodiode 186. The electron-hole pairs results in the transfer of electrons near the second side 194 of the photodiode where there is little to no incident light. When an event occurs sufficient to create electron/hole pairs, an electron flow and a hole flow are produced, thus providing a current to produce a signal associated with the pixel.

In various implementations, the image sensor 178 may include a storage node 208 within the second side 192 of the semiconductor layer 180. In such implementations, the storage node 208 may be shaded by the light shield layer 298 when incident light strikes the image sensor 178.

Still referring to FIG. 22, the image sensor may include a storage gate 210 coupled to the storage node 208. In various implementations, the storage gate 210 may be within the second dielectric layer 184. Similarly, in various implementations the second dielectric layer 184 may also include a transfer gate 212. The transfer gate 212 may be directly coupled to the photodiode 186.

In various implementations, the image sensor 178 may be considered a front side image (FSI) sensor. The image sensor 178 of FIG. 22 may be able to detect longer wavelengths due to the light absorbing layer, as previously described with regards to FIGS. 21 and 24. Further, in various implementations, the image sensor 178 may be as efficient as the image sensors of FIGS. 21 and 24.

In places where the description above refers to particular implementations of image sensors and related methods and implementing components, sub-components, methods and sub-methods, it should be readily apparent that a number of modifications may be made without departing from the spirit thereof and that these implementations, implementing components, sub-components, methods and sub-methods may be applied to other image sensors and related methods.

What is claimed is:

1. An image sensor, comprising:
a semiconductor layer comprising a photodiode;
one of a metal layer or metal silicide layer directly coupled to a first side of the photodiode; and
a storage node coupled within a second side of the photodiode;
wherein the one of the metal layer or metal silicide layer is configured to absorb one or more predetermined wavelengths of incident light and correspondingly heat a portion of the semiconductor layer.

2. The image sensor of claim 1, wherein the storage node is configured to be shaded by the one of the metal layer or metal silicide layer when the incident light hits the one of the metal layer or metal silicide layer.

3. The image sensor of claim 1, further comprising a lens, the one of the metal or metal silicide layer coupled between the lens and the semiconductor layer, the lens configured to direct the incident light towards the one of the metal or metal silicide layer.

4. The image sensor of claim 1, wherein the image sensor comprises a backside integrated (BSI) sensor.

5. The image sensor of claim 1, further comprising an anti-reflective coating coupled to the one of the metal or metal silicide layer.

6. The image sensor of claim 1, wherein the one of the metal or metal silicide layer is configured to generate electron-hole pairs in the photodiode through the heating of the portion of the photodiode.

7. An image sensor, comprising:
a first dielectric layer coupled over a semiconductor layer, the semiconductor layer comprising a photodiode;
a lens coupled over the first dielectric layer;
a light absorbing layer coupled over a first side of the photodiode; and
a storage node coupled within a second side of the photodiode.

8. The image sensor of claim 7, wherein the lens is configured to focus incident light onto the light absorbing layer.

9. The image sensor of claim 7, wherein the light absorbing layer is configured to absorb one or more predetermined wavelengths of incident light, and correspondingly generate electron-hole pairs through heating a portion of the photodiode.

10. The image sensor of claim 7, wherein the storage node is configured to be in a shadow of the light absorbing layer when incident light strikes the light absorbing layer.

11. The image sensor of claim 7, wherein the light absorbing layer comprises tantalum.

12. The image sensor of claim 7, wherein the image sensor comprises a backside integrated (BSI) sensor.

13. An image sensor, comprising:
a first dielectric layer coupled over a first side of a semiconductor layer, the semiconductor layer comprising a photodiode;
a lens coupled over the first dielectric layer;
an anti-reflective coating configured to allow one or more predetermined wavelengths of light to pass through the semiconductor layer;
a light absorbing layer coupled within a second side of the photodiode;
wherein the light absorbing layer is configured to absorb one or more predetermined wavelengths of incident light and generate electron-hole pairs within the photodiode through heating a portion of the photodiode.

14. The image sensor of claim 13, further comprising a light shield layer coupled between the first dielectric layer and the semiconductor layer, the light shield layer comprising an opening comprising the anti-reflective coating.

15. The image sensor of claim 13, further comprising a storage node comprised within a second side of the semiconductor layer.

16. The image sensor of claim 15, wherein the storage node is substantially shielded from incident light by a light shield layer coupled between the first dielectric layer and the semiconductor layer.

17. The image sensor of claim 13, further comprising a second dielectric layer coupled to the second side of the semiconductor layer.

18. The image sensor of claim 17, further comprising a storage gate coupled within the second dielectric layer, the storage gate directly coupled to a storage node within a second side of the semiconductor layer.

19. The image sensor of claim 17, further comprising a transfer gate coupled within the second dielectric layer and directly coupled to the photodiode.

20. The image sensor of claim 13, wherein the light absorbing layer comprises tantalum.
